(19) United States
(12) Patent Application Publication
(10) Pub. No.: US 2024/0255545 A1
(43) Pub. Date: Aug. 1, 2024

(54) PROBE CARD AND TEST APPARATUS INCLUDING PROBE CARD

(71) Applicant: LX SEMICON CO., LTD., Daejeon (KR)

(72) Inventors: Min Suk KIM, Daejeon (KR); Seung Il HONG, Daejeon (KR)

(73) Assignee: LX SEMICON CO., LTD., Daejeon (KR)

(21) Appl. No.: 18/399,918

(22) Filed: Dec. 29, 2023

(30) Foreign Application Priority Data
Jan. 31, 2023 (KR) 10-2023-0012342

(51) Int. Cl. G01R 1/073; G01R 1/067

(52) U.S. Cl. CPC G01R 1/07342; G01R 1/06711

(57) ABSTRACT

A semiconductor chip disposed on a wafer may be tested by using a probe card provided at an upper portion of a chamber for testing the semiconductor chip. A signal generated from a test module is transmitted to a needle included in the probe card, so that abnormality in the semiconductor chip may be tested.

### CROSS-REFERENCE TO RELATED APPLICATION

This application claims the priority of Korean Patent Application No. 10-2023-0012342, filed on Jan. 31, 2023, which is hereby incorporated by reference in its entirety.

### BACKGROUND

### Field of the Disclosure

The present disclosure relates to a probe card for testing an element to be tested, and to a test apparatus including the probe card.

### Description of the Background

Various processes may be performed to produce a finished semiconductor package from a semiconductor chip. For example, a semiconductor production process may include a process of fabricating semiconductor wafers, a front-process, an assembly process, and the like. In this case, a plurality of semiconductor chips may be formed on a wafer through the front process among the semiconductor production processes, and semiconductor chips required for assembling a semiconductor package may be obtained through a wafer cutting process.

According to an aspect, before performing the wafer cutting process, a process of selecting semiconductor chips to be used for assembling the semiconductor package may be performed. For example, electrical characteristics of the semiconductor chip may be tested to detect initial defects of the semiconductor chip on the wafer. Test apparatus for testing the semiconductor chip formed on the wafer may be composed of a test module configured to generate a test signal to determine whether there is abnormality in the semiconductor chip and a probe station installed in a chamber to transmit the test signal to the semiconductor chip. A probe card that is in contact with each chip pad of the semiconductor chip formed on the wafer may be installed in the probe station.

According to an aspect, the probe card has a plurality of needles (e.g., probe pins) fixed to a body of the probe card, and the signal generated from the test module may be transmitted to each of the needles installed on the probe card. The signal transmitted to the needle is transmitted to a chip pad (or a bonding pad or a bump) of the semiconductor chip on the wafer with which each needle is in contact, so that the abnormality in the semiconductor chip may be tested.

Meanwhile, a fixing member (e.g., epoxy) may be used to fix the needle. As the plurality of needles fixed by the fixing member are arranged in a stacked shape or a diagonal shape, a length of the needle exposed to the outside through the fixing member may not be constant. When the length of the needle is not constant, the pressure when the needle is in contact with the chip pad may not be maintained constant. When the pressure of the needle is not constant, the needle may not be in contact with the bonding pad of a test object (e.g., semiconductor chip) with the same pressure, thereby occurring difficulties in testing. Therefore, a method is needed to enable that the needle of the probe card is in contact with the test object with the same pressure.

### SUMMARY

Accordingly, the present disclosure is directed to a probe card and a test apparatus including the same that substantially obviate one or more of problems due to limitations and disadvantages described above.

More specifically, the present disclosure is to provide a probe card in which a needle of the probe card may be in contact with a test object with the same pressure and a test apparatus including the probe card when testing whether there are errors in a semiconductor chip formed on a wafer through the test apparatus.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a probe card includes a printed circuit board (PCB), a needle electrically connected to one side surface of the PCB, and a fixing member configured to fix the other side of the needle, wherein the other side of the needle passes through the fixing member to be exposed to the outside of the fixing member, and a first surface of the side surfaces of the fixing member to which the needle is exposed forms a curved surface.

In another aspect of the present disclosure, a probe card includes a printed circuit board (PCB), a needle electrically connected to one side of the PCB, and a fixing member configured to fix the other side of the needle, wherein the other side of the needle passes through the fixing member to be exposed to the outside of the fixing member, and a first surface of the side surfaces of the fixing member to which the needle is exposed forms an inclined surface.

In a further aspect of the present disclosure, a test apparatus includes a test module configured to generate a test signal to transmit the test signal to a printed circuit board (PCB) and process the received signal and a chamber including a chuck on which an element to be tested is disposed and a probe card fixed to an upper portion of the chuck to test the element to be tested, wherein the probe card includes a printed circuit board (PCB), a needle electrically connected to one side of the PCB, and a fixing member configured to fix the other side of the needle, wherein the other side of the needle passes through the fixing member to be exposed to the outside of the fixing member, and a first surface of the side surfaces of the fixing member to which the needle is exposed forms a curved surface.

As described above, according to the aspect, an exposed surface of a fixing member for fixing a needle is configured in a curved or an inclined surface, so that when a semiconductor chip formed on a wafer is tested for errors through a test apparatus, the needle of a probe card may be in contacted with a test object with the same pressure.

In addition, according to the aspect, electrical characteristics may be tested while applying the same pressure to all bonding pads of the semiconductor chip, thereby significantly improving a product yield and engineer convenience, and it does not require excessive contact with the needle, thereby extending a lifespan of a probe.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a cross-sectional view of a test apparatus according to an aspect of the present disclosure;

FIG. 2 is a cross-sectional view of a probe card according to an aspect of the present disclosure;

FIG. 3A is a diagram illustrating contact between a needle of a probe card and a bump of a semiconductor chip according to an aspect of the present disclosure;

FIG. 3B is a diagram illustrating contact between a needle of a probe card and a bump of a semiconductor chip according to an aspect of the present disclosure;

FIG. 4A is a diagram illustrating a structure of a bonding pad disposed on a semiconductor chip according to an aspect of the present disclosure;

FIG. 4B is a diagram illustrating a structure of a bonding pad disposed on a semiconductor chip according to an aspect of the present disclosure;

FIG. 4C is a diagram illustrating a structure of a bonding pad disposed on a semiconductor chip according to an aspect of the present disclosure;

FIG. 5 is a diagram illustrating an exposed surface of a fixing member according to an aspect of the present disclosure;

FIG. 6 is a diagram illustrating an exposed surface of a fixing member according to an aspect of the present disclosure;

FIG. 7 is a diagram illustrating a fixing member to which a needle is fixed according to an aspect of the present disclosure;

FIG. 8 is a diagram illustrating a process for fixing a needle to a fixing member according to an aspect of the present disclosure;

FIG. 9 is a diagram illustrating a fixing member to which a needle is fixed according to an aspect of the present disclosure; and

FIG. 10 is a diagram illustrating a fixing member to which a needle is fixed according to an aspect of the present disclosure.

### DETAILED DESCRIPTION

Hereinafter, some aspects of the present disclosure will be described in detail with reference to exemplary drawings. In adding reference numerals to elements in each drawing, the same elements will be designated by the same reference numerals as far as possible, although they are shown in different drawings. In addition, in the following description of the present disclosure, a detailed description of known functions and configurations incorporated herein will be omitted when it is determined that the description may make the subject matter of the present disclosure rather unclear.

In addition, terms, such as first, second, A, B, (a), (b) or the like may be used herein when describing elements of the present disclosure. These terms are merely used to distinguish one element from other elements, and a property, an order, a sequence or the like of a corresponding element are not limited by the terms. When it is described in the specification that an element is “connected,” “coupled” or “joined” to another element, it should be understood that the element may be directly connected, coupled or joined to the other elements, but another element may be “connected,” “coupled,” and “joined” between the element and other elements.

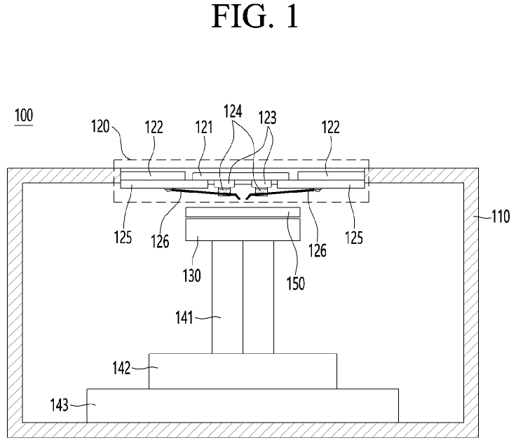

FIG. 1 is a cross-sectional view of a test apparatus according to an aspect.

Referring to FIG. 1, a test apparatus 100 may include a chuck 130 on which an element to be tested (e.g., a wafer 150) is disposed inside a chamber 110. A plurality of driving units 141, 142, and 143 may be disposed under the chuck 130. For example, a first driving unit 141, a second driving unit 142, and a third driving unit 143 may be disposed under the chuck 130. The first driving unit 141 may move the chuck 130 in a Z-axis direction. The chuck 130 may be lowered or raised according to driving of the first driving unit 141. The second driving unit 142 may move the chuck 130 in an X-axis direction. The third driving unit 143 may move the chuck 130 in a Y-axis direction. A position of the chuck 130 may be adjusted in the X-axis, Y-axis, or Z-axis directions according to driving of the first driving part 141, the second driving part 142, and the third driving part 143. The element to be tested (e.g., wafer 150) disposed on the chuck 130 may move in the same direction according to moving of the position of the chuck 130.

According to an aspect, a probe card 120 for testing the element to be tested (e.g., the wafer 150) may be installed at an upper portion of the chamber 110. The probe card 120 may receive a test signal from a test module provided outside the chamber 110 and transmit the received test signal to the element to be tested (e.g., the wafer 150).

According to an aspect, the probe card 120 may include a stiffening plate 121, a stiffener 122, an auxiliary ring 123, a fixing member 124, a printed circuit board (PCB) 125, and a needle 126. The stiffener 122 may be coupled to the upper portion of the chamber 110, and thus the probe card 120 may be fixed to the upper portion of the chamber 110. The PCB 125 may have an opening in a center thereof and may be fixed to one side of a lower surface of the stiffener 122. The stiffening plate 121 may be fixed to an upper surface of the PCB 125. The auxiliary ring 123 may be fixed to one side of an upper surface of the stiffening plate 121 and may be exposed through the opening in the center of the PCB 125. The fixing member 124 may be installed on a lower surface of the auxiliary ring 123 to be fixed thereto. One side of the needle 126 may be electrically connected to the PCB 125 by a soldering part (e.g., soldering), and the other side thereof may be fixed to the fixing member 124. According to an aspect, the other side of the needle 126 may pass through the fixing member 124 to be exposed to the outside of the fixing member 124. In consideration of a shape of the needle 126, the needle shown in FIG. 1 may be referred to as a cantilever type needle, but the aspect is not limited to the term.

According to an aspect, when the chuck 130 rises, the element to be tested (e.g., wafer 150) disposed on the chuck 130 may rise. As the element to be tested (e.g., the wafer 150) rises, an end of the other side of the needle 126 is in contact with a bump formed on the element to be tested (e.g., the wafer 150), and thus the received test signal from the test module may be transmitted to the element to be tested. Accordingly, the test module may test abnormality of the element to be tested (e.g., the wafer 150) through the probe card 120.

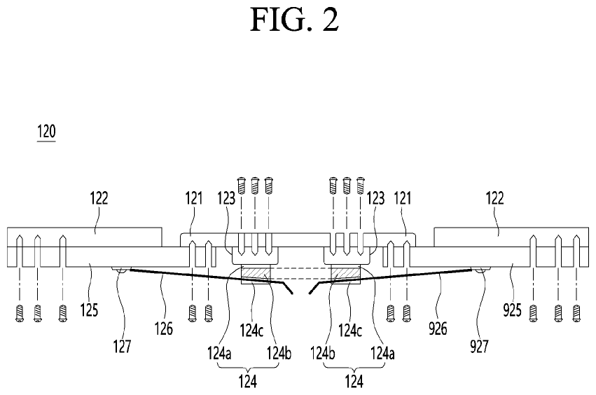

FIG. 2 is a cross-sectional view of a probe card according to an aspect.

Referring to FIG. 2, according to an aspect, the probe card 120 may include a stiffening plate 121, a stiffener 122, an auxiliary ring 123, a fixing member 124, a printed circuit board (PCB) 125, and a needle 126. The stiffener 122 may be coupled to an upper portion of the chamber 110, and thus the probe card 120 may be fixed to the upper portion of the chamber 110. The PCB 125 may have an opening in a center thereof and may be fixed to one side of a lower surface of the stiffener 122 by fastening parts. The stiffening plate 121 may be fixed to an upper surface of the PCB 125 by the fastening parts.

According to an aspect, the auxiliary ring 123 may be fixed to one side of a lower surface of the stiffening plate 121 by the fastening parts and may be exposed through the opening of the center of the PCB 125. The fixing member 124 may be installed on a lower surface of the auxiliary ring 123 to be fixed thereto. According to an aspect, the fixing member 124 may include a first epoxy fixing part 124a installed on the lower surface of the auxiliary ring 123, a ceramic spider 124b (e.g., a ceramic ring) installed on a lower surface of the first epoxy fixing part 124a, and a second epoxy fixing part 124c installed on a lower surface of the ceramic spider 124b. For example, the first epoxy fixing part 124a may fix the ceramic spider 124b to the auxiliary ring 123. The second epoxy fixing part 124c may fix the needle 126 to the ceramic spider 124b. According to an aspect, one end of the needle 126 may be electrically connected to the PCB 125 by a solder ball 127. The other side of the needle 126 may be fixed by the fixing member 124 (e.g., the second epoxy fixing part 124c).

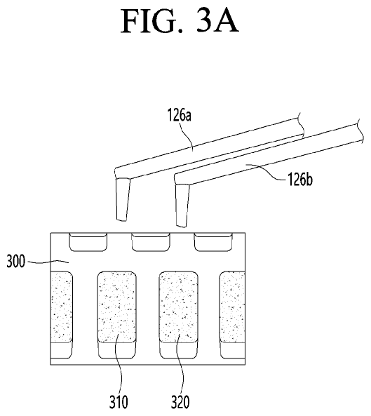

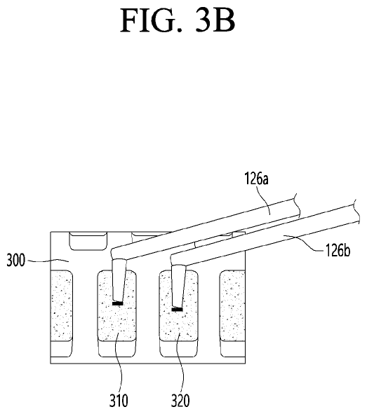

FIGS. 3A and 3B are diagrams illustrating contact between a needle of a probe card and a bump of a semiconductor chip according to an aspect.

Referring to FIGS. 3A and 3B, while needles 126a and 126b of a probe card 120 are in contact with bumps 310 and 320 of a wafer 300 (e.g., a semiconductor chip), the needles 126a and 126b may pass through in to the bumps 310 and 320. For example, a first needle 126a may be in contact with a first bump 310, and a second needle 126b may be in contact with a second bump 320. For example, as a lower wafer 300 moves up and down in a state in which a probe card 120 on which the needles 126a and 126b are mounted is fixed, the needles 126a and 126b may be in contact with the bumps 310 and 320 of the wafer 300 (e.g., the semiconductor chip).

According to an aspect, when the wafer 300 is produced as a product used in a test process, the needles 126a and 126b mounted on the above-described probe card 120 may transmit signals while being in contact with the bumps 310 and 320 of the wafer 300. By checking whether signals fed back and received through the needles 126a and 126b are normal, it is possible to check whether the semiconductor chip is defective. For example, when the semiconductor chip is a display driver IC (DDI), a number of needles 126a and 126b mounted on the probe card 120 may be thousands or more.

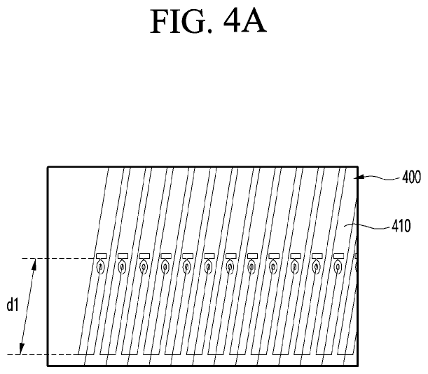

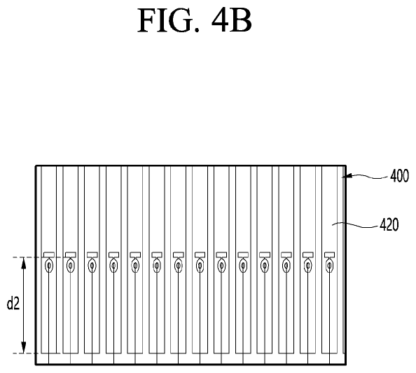

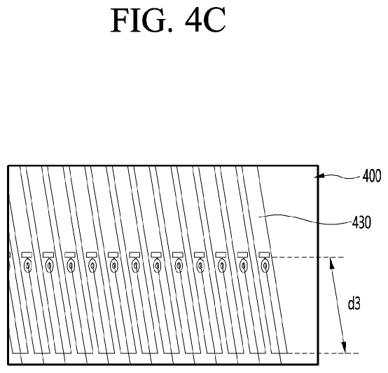

FIGS. 4A, 4B, and 4C are diagrams illustrating a structure of a bonding pad disposed on a semiconductor chip according to an aspect.

Referring to FIGS. 4A, 4B, and 4C, a plurality of contact pads 410, 420, and 430 may be formed on a wafer 400 (e.g., a semiconductor chip). The contact pads 410, 420, and 430 may be formed diagonally as shown in FIGS. 4A and 4C or may be formed vertically as shown in FIG. 4B. For example, the contact pad 420 may be formed vertically in a central portion of the wafer 400 as shown in FIG. 4B, and the contact pads 410 and 430 may be formed diagonally in left-side and right-side portions of the wafer 400 as shown in FIGS. 4A and 4C, respectively. As such, as arrangement forms of the central portion and side portions are different from each other, lengths of the contact pads may be different. For example, a length d1 of a left contact pad 410 and a length d3 of a right contact pad 430 may be different from a length d2 of a central contact pad 420. As such, as the lengths of the contact pads are different, lengths of the needles in contact with the contact pads are different, and thus a change in pressure between the needles may occur. For example, pressure of the needles applied to the left or right contact pads 410 and 430 may be relatively weak compared to the central contact pad 420, so that contact may not be made properly. Accordingly, a phenomenon in which electrical signals are not transmitted well from the needles to the contact pads 410 and 430 may occur.

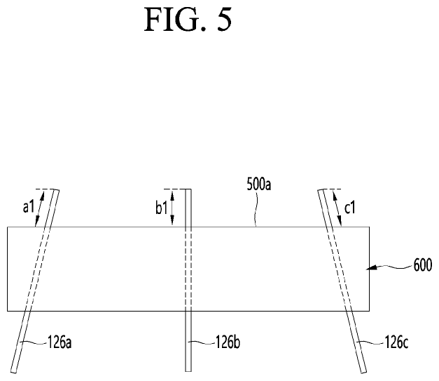

FIG. 5 is a diagram illustrating an exposed surface of a fixing member according to an aspect.

Referring to FIG. 5, a plurality of needles 126a, 126b, and 126c may pass through a fixing member 500 to be exposed to the outside of the fixing member 500. For example, the fixing member 500 may be made of an epoxy material, but the aspect is not limited thereto. FIG. 5 is a plan view of the fixing member 500, and a first surface 500a of side surfaces of the fixing member 500 on which needles are exposed may form a plane as shown in FIG. 5. According to an aspect, one side of each of the needles 126a, 126b, and 126c may be electrically connected to a printed circuit board (PCB) by a solder ball. The other side of each of the needles 126a, 126b, and 126c may pass through the fixing member 500 and may be exposed through the first surface 500a of the fixing member 500. The other side of each of the needles 126a, 126b, and 126c exposed to pass through the fixing member 500 may be in contact with a contact pad of a wafer (e.g., a semiconductor chip).

According to an aspect, when the first surface 500a of the side surfaces of the fixing member 500 on which the needles are exposed forms a plane as shown in FIG. 5, lengths of exposed portions of a central needle 126b and side needles 126a and 126c may be different from each other. For example, a length a1 of an exposed portion of the needle 126a disposed on the left may be different from a length b1 of an exposed portion of the needle 126b disposed in the center, and a length c1 of an exposed portion of the needle 126c disposed on the right may be different from the length b1 of the exposed portion of the needle 126b disposed in the center. As such, as the lengths of the exposed portions of the central needle 126b and the side needles 126a and 126c are different from each other, pressure between the needles 126a, 126b and 126c may not be maintained constant. When the pressure between the needles 126a, 126b, and 126c is not maintained constant, it may not be in contact with a bonding pad of a test object (e.g., a semiconductor chip) with the same pressure, thereby occurring difficulty in testing.

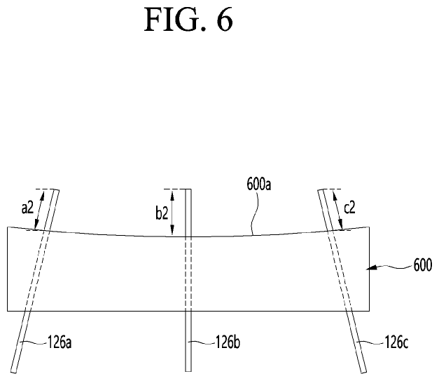

FIG. 6 is a diagram illustrating an exposed surface of a fixing member according to an aspect.

Referring to FIG. 6, a plurality of needles 126a, 126b, and 126c may pass through a fixing member 600 to be exposed to the outside of the fixing member 600. For example, the fixing member 600 may be made of an epoxy material, but the aspect is not limited thereto. FIG. 6 is a plan view of the fixing member 600, a first surface 600a of side surfaces of the fixing member 600 on which needles are exposed may form a curved (or round type) surface as shown in FIG. 6. Although FIG. 6 illustrates a case in which the first surface 600a is a curved surface, it may also form a bended surface according to various aspects. For example, any aspect in which center and side portions of the first surface 600a do not form a plane may be applied.

According to an aspect, one side of each of the needles 126a, 126b, and 126c may be electrically connected to a printed circuit board (PCB) by a solder ball. The other side of each of the needles 126a, 126b, and 126c may pass through the fixing member 600 and may be exposed through the first surface 600a of the fixing member 600. The other side of each of the needles 126a, 126b, and 126c exposed to pass through the fixing member 600 may be in contact with a contact pad of a wafer (e.g., a semiconductor chip).

According to an aspect, when the first surface 600a of the side surfaces of the fixing member 600 on which the needle is exposed forms a curved surface as shown in FIG. 6, lengths of exposed portions of a central needle 126b and side needles 126a and 126c may be the same as each other. For example, a length a2 of an exposed portion of the needle 126a disposed on the left may be equal to a length b2 of an exposed portion of the needle 126b disposed in the center, and a length c2 of an exposed portion of the needle 126c disposed on the right may be equal to the length b2 of the exposed portion of the needle 126b disposed in the center. As such, as the lengths of the exposed portions of the central needle 126b and the side needles 126a and 126c are the same as each other, pressure between the needles 126a, 126b and 126c may be maintained constant. According to an aspect, when testing the semiconductor chip mixed with diagonal bonding pads as shown in FIGS. 4A, 4B, and 4C, electrical characteristics may be tested while applying the same pressure to all bonding pads. Accordingly, product yield and engineer convenience are significantly improved, and excessive pressure is not required for contact of the needles, thereby extending a lifespan of a probe.

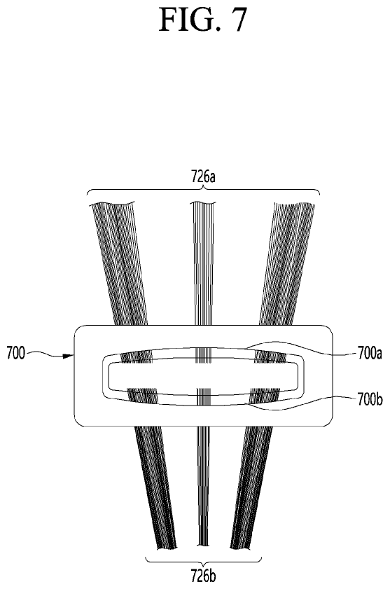

FIG. 7 is a diagram illustrating a fixing member to which a needle is fixed according to an aspect.

Referring to FIG. 7, according to an aspect, the other side of upper needles 726a may be exposed toward a center of a fixing member 700 through a first surface 700a from an upper portion to a lower portion of the fixing member 700 when viewed in a plane. In addition, the other side of lower needles 726b may be exposed toward the center of the fixing member 700 through the first surface 700b from the lower portion to the upper portion of the fixing member 700 when viewed in a plane. According to an aspect, as a wafer rises and is positioned at the center of the fixing member 700, the upper needles 726a and the lower needles 726b may be in contact with bonding pads formed on the wafer. As described above in FIG. 6, as lengths of the upper needles 726a exposed through the first surface 700a from the upper portion to the lower portion of the fixing member 700 are the same as each other, the upper needles 726a may be in contact with the bonding pads with the same pressure. In addition, as lengths of the lower needles 726b exposed through the first surface 700b from the lower portion to the upper portion of the fixing member 700 are the same as each other, the lower needles 726b may be in contact with the bonding pads with the same pressure.

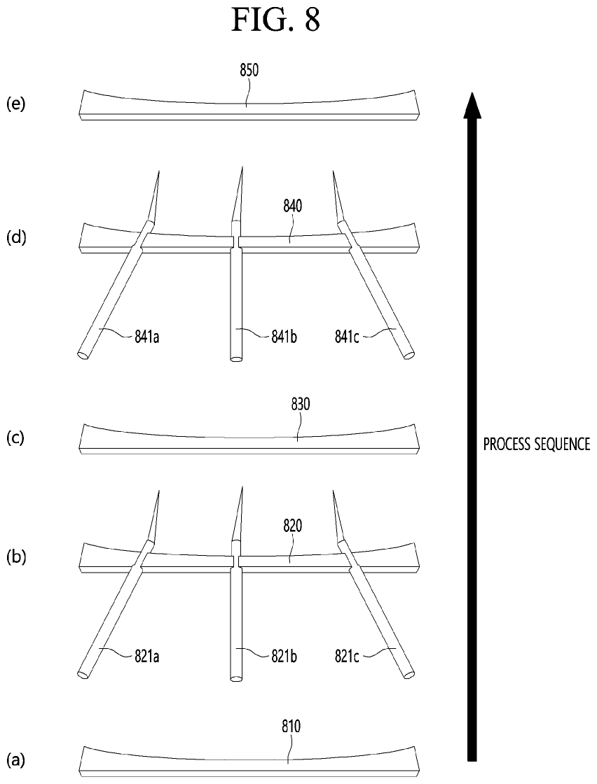

FIG. 8 is a diagram illustrating a process for fixing a needle to a fixing member according to an aspect.

Referring to FIG. 8, according to an aspect, as a first step (step (a)) of the process for fixing the needle to the fixing member, a first base film 810 may be prepared. Next, as a second step (step (b)), first layer needles 821a, 821b, and 821c may be inserted into and fixed to a first fixing member 820 (e.g., first epoxy). The first fixing member 820 into which the first layer needles 821a, 821b, and 821c are inserted may be stacked on the first base film 810.

According to an aspect, as a third step (step (c)), a second base film 830 may be prepared. The second base film 830 may be stacked on the first fixing member 820. Next, as a fourth step (step (d)), second layer needles 841a, 841b, and 841c may be inserted into and fixed to a second fixing member 840 (e.g., second epoxy). The second fixing member 840 into which the second layer needles 841a, 841b, and 841c are inserted may be stacked on the second layer base film 820. Finally, as a fifth step (step (e)), an uppermost layer fixing member 850 (e.g., uppermost layer epoxy) may be prepared. The uppermost fixing member 850 may be stacked on the second fixing member 840.

According to an aspect, a first surface of each of the base films 810 and 830 and each of the fixing members 820, 840, and 850 may form a curved surface as described above. For example, the first surface in which the other side of the first layer needles 821a, 821b, and 821c is exposed among side surfaces of the first fixing member 820 may form a curved surface as shown in the drawing. In addition, the first surface in which the other side of the second layer needles 841a, 841b, and 841c is exposed among side surfaces of the second fixing member 840 may form a curved surface as shown in the drawing.

According to an aspect, FIG. 8 illustrates a form in which the first layer needles 821a, 821b, and 821c and the second layer needles 841a, 841b, and 841c are stacked but three or more layers of needles may be added between the second fixing member 840 and the uppermost fixing member 850. For example, a third fixing member into which third layer needles are inserted may be further added between the second fixing member 840 and the uppermost fixing member 850.

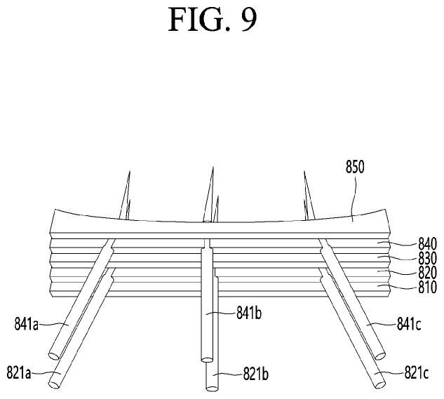

FIG. 9 is a diagram illustrating a fixing member to which a needle is fixed according to an aspect.

Referring to FIG. 9, according to an aspect, the fixing member into which a plurality of needles are inserted may be formed through the process of FIG. 8 described above. For example, the first base film 810, the first fixing member 820, the second base film 830, the second fixing member 840, and the uppermost fixing member 850 may be stacked from the lower portion to the upper portion. According to an aspect, the other side of the first layer needles 821a, 821b, and 821c may pass through the first fixing member 820 to be exposed to the outside. In addition, the other side of the second layer needles 841a, 841b, and 841c may pass through the second fixing member 840 to be exposed to the outside. As described above, a first surface in which the other side of the first layer needles 821a, 821b, and 821c is exposed among side surfaces of the first fixing member 820 or the second fixing member 840 or a first surface in which the other side of the second layer needles 841a, 841b, and 841c is exposed may be formed as a curved surface.

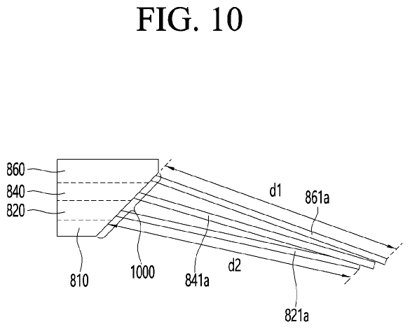

FIG. 10 is a diagram illustrating a fixing member to which a needle is fixed according to an aspect.

Referring to FIG. 10, according to an aspect, the other side of needles 821a, 841a, and 861a may be exposed to the outside through a first surface 1000 of the fixing member when viewed on a side surface. FIG. 10 illustrates a form in which three layers of needles are stacked, but the aspect is not limited thereto. For example, as described above in FIGS. 8 and 9, two layers of needles may be stacked, or four or more layers of needles may be stacked. According to an aspect, the first layer needle 821a may pass through the first fixing member 820 to be exposed to the outside. The second layer needle 841a may pass through the second fixing member 840 to be exposed to the outside. The third layer needle 861a may pass through the third fixing member 860 to be exposed to the outside.

According to an aspect, when viewed on a side surface, the first surface 1000 of the fixing member may form an inclined surface. Accordingly, a length d2 at which the other side of the first layer needle 821a is exposed to the outside may be the same as a length d1 at which the other side of the third layer needle 861a is exposed to the outside. In addition, a length at which the other side of the second layer needle 841a is exposed to the outside may be the same as the length d2 at which the other side of the first layer needle 821a is exposed to the outside and the length d1 at which the other side of the third layer needle 861a is exposed to the outside. As such, as the lengths of the needles 821a, 841a, and 861a exposed through each layer of the fixing member are the same as each other, the needles 821a, 841a, and 861a may be in contact with the bonding pads with the same pressure.

As described above, according to the aspect, an exposed surface of a fixing member for fixing a needle is configured in a curved or an inclined surface, so that whether there are errors in a semiconductor chip formed on a wafer through a test apparatus, the needle of a probe card may be in contacted with a test object with the same pressure.

In addition, according to the aspect, electrical characteristics may be tested while applying the same pressure to all bonding pads of the semiconductor chip, thereby significantly improving a product yield and engineer convenience, and it does not require excessive contact with the needle, thereby reducing the risk of probe damage and extending a lifespan of a probe.

It will be apparent to those skilled in the art that various modifications and variations can be made in the probe card and the test apparatus including the same of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A probe card comprising:
a needle;
a printed circuit board (PCB) electrically connected to one side of the needle; and
a fixing member configured to fix the other side of the needle,
wherein the fixing member fixes a part of the other side of the needle such that an end of the other side of the needle passes through to be exposed to the outside, and
a whole or part of a side surface of the fixing member through which the end of the other side of the needle passes is a curved surface.

2. The probe card of claim 1, wherein at least a part of the fixing member includes epoxy.

3. The probe card of claim 1, wherein the fixing member includes a concave surface in a region through which the needle passes of the side surface through which the end of the other side of the needle passes.

4. The probe card of claim 1, wherein a width of an upper surface of a central region smaller than that of an upper surface of an edge region in the fixing member.

5. The probe card of claim 1, further comprising:
a stiffener of which an upper surface is fixed to a chamber and a lower surface is fixed to a periphery of the PCB;
a stiffening plate of which a lower surface is fixed to a central portion of the PCB; and
an auxiliary ring disposed between the stiffening plate and the fixing member.

6. The probe card of claim 5, wherein the fixing member is disposed in a central region of a lower surface of the stiffening plate.

7. The probe card of claim 5, wherein the fixing member further includes:
a first epoxy fixing part installed on a lower surface of the auxiliary ring;
a ceramic spider installed on a lower surface of the first epoxy fixing part; and
a second epoxy fixing part installed on a lower surface of the ceramic spider.

8. The probe card of claim 7, wherein the first epoxy fixing part fixes the ceramic spider to the auxiliary ring.

9. The probe card of claim 7, wherein the second epoxy fixing part fixes the needle to the ceramic spider.

10. The probe card of claim 1, wherein one end of the needle is electrically connected to the PCB by a solder ball.

11. A probe card comprising:
a needle;
a printed circuit board (PCB) electrically connected to one side of the needle; and
a fixing member configured to fix the other side of the needle,
wherein the fixing member fixes a part of the other side of the needle such that an end of the other side of the needle passes through to be exposed to the outside, and
a whole or part of a side surface of the fixing member through which the end of the other side of the needle passes is an inclined surface.

12. The probe card of claim 11, wherein at least a part of the fixing member includes epoxy.

13. The probe card of claim 11, wherein the inclined surface of the fixing member is formed when an angle between the side surface through which the end of the other side of the needle passes and an upper surface thereof is an acute angle and an angle between the side surface through which the end of the other side of the needle passes and a lower surface thereof is an obtuse angle.

14. The probe card of claim 11, further comprising:
a stiffener of which an upper surface is fixed to a chamber and a lower surface is fixed to a periphery of the PCB;
a stiffening plate of which a lower surface is fixed to a central portion of the PCB; and
an auxiliary ring disposed between the stiffening plate and the fixing member.

15. The probe card of claim 14, wherein the fixing member is disposed in a central region of a lower surface of the stiffening plate.

16. A test apparatus comprising:
a test module configured to generate a test signal to transmit the test signal to a printed circuit board (PCB) and process the received signal; and
a chamber including a chuck on which an element to be tested is disposed and a probe card fixed to an upper portion of the chuck to test the element to be tested,
wherein the probe card includes:
a needle;
a printed circuit board (PCB) electrically connected to one side of the needle; and
a fixing member configured to fix the other side of the needle,
wherein the fixing member fixes a part of the other side of the needle such that an end of the other side of the needle passes through to be exposed to the outside, and
a whole or part of a side surface of the fixing member through which the end of the other side of the needle passes is a curved surface.

17. The test apparatus of claim 16, wherein the side surface of the fixing member through which the end of the other side of the needle passes has a curved surface formed in a horizontal direction.

18. The test apparatus of claim 16, wherein the side surface of the fixing member through which the end of the other side of the needle passes includes a concave surface in a region through which the needle passes.

19. The test apparatus of claim 16, wherein the side surface of the fixing member through which the end of the other side of the needle passes has an inclined surface formed in a vertical direction.

20. The test apparatus of claim 19, wherein the inclined surface of the fixing member is formed when an angle between the side surface through which the end of the other side of the needle passes and an upper surface thereof is an acute angle and an angle between the side surface through which the end of the other side of the needle passes and a lower surface thereof is an obtuse angle.
